(19) United States
(12) Patent Application Publication
(10) Pub. No.: US 2026/0225494 A1
(43) Pub. Date: Aug. 6, 2026

(54) DYNAMIC RESERVE ALLOCATION FOR ELECTRIC VEHICLES

(71) Applicant: FORD GLOBAL TECHNOLOGIES, LLC, Dearborn, MI (US)

(72) Inventors: Keith WESTON, Canton, MI (US); Stuart C. SALTER, White Lake, MI (US); John Robert VAN WIEMEERSCH, Novi, MI (US)

(21) Appl. No.: 19/047,397

(22) Filed: Feb. 6, 2025

(51) Int. Cl. B60L 58/16; B60L 3/12; B60L 58/14

(52) U.S. Cl. CPC B60L 58/16; B60L 3/12; B60L 58/14; B60L 2240/545; B60L 2240/622; B60L 2240/66; B60L 2240/72; B60L 2250/16; B60L 2260/52; B60L 2260/54

(57) ABSTRACT

Systems and methods for managing reserve battery capacity in vehicles are disclosed. The method includes monitoring battery usage patterns to calculate a battery life score and determining a reserve battery capacity based on the calculated battery life score. When the vehicle is located a predefined distance from a charging facility, the method calculates an extended driving range achievable with the reserve battery capacity. A reserve battery capacity release option is presented to a user, including the associated extended driving range and the battery life score effect of the reserve battery capacity release. Upon user confirmation, the reserve battery capacity is released, and the battery life score and reserve battery capacity are dynamically adjusted based on the effect of the reserve battery capacity release.

### TECHNICAL FIELD

The present disclosure relates to battery management systems for electric vehicles.

### BACKGROUND

Off-pavement adventures which may be cement, asphalt, or paver bricks, and professional missions in remote or difficult situations often require vehicles with sufficient energy reserves to navigate unexpected challenges. These activities may involve greater energy consumption than on-pavement driving, reducing vehicle range and potentially leaving users stranded.

### SUMMARY

In one aspect of the disclosure, a method of managing an electric vehicle battery is presented. The method includes monitoring the battery usage patterns of an electric vehicle to calculate a battery life score and determining a reserve battery capacity based on the battery life score. The method further includes calculating an extended driving range, when the electric vehicle is a predefined distance from a charging facility, based on the reserve battery capacity. The method also further includes displaying a reserve battery capacity release option to a user with the associated extended driving range and battery life score effect of the reserve battery capacity release and releasing the reserve battery capacity upon user confirmation. The battery life score is adjusted along with the reserve battery capacity based on the effect of the reserve battery capacity release.

The method may include monitoring battery usage patterns that includes tracking depth of discharge events and charge levels of the battery.

The method may include calculating the battery life score by accounting for thermal exposure and charging frequency.

The method may include determining the reserve battery capacity by ensuring the release does not exceed a predefined limit to maintain long-term battery health.

The method may include dynamically adjusting the predefined distance based on topographical data and weather conditions.

The method may include displaying the reserve battery capacity release option by presenting the user with a graphical interface showing projected range and battery life effect.

The method may include releasing the reserve battery capacity by applying a staged release process based on the electric vehicle’s operational requirements.

The method may include adjusting the battery life score by updating thresholds for future reserve capacity releases.

In another aspect of the disclosure, a battery management controller for managing battery reserve capacity in an electric vehicle is presented. The battery management controller includes a traction battery configured to store and supply electrical energy to an electric vehicle. The battery management controller further includes a global navigation satellite system configured to determine a location of the electric vehicle and its distance from charging facilities. The battery management controller also includes a processor configured to monitor usage patterns of the traction battery to calculate a battery life score and determine a reserve battery capacity based on the battery life score. The processor is further configured to receive information from the global navigation satellite system indicating the electric vehicle is farther from a charging facility than a distance achievable with a remaining capacity of the traction battery and release the reserve battery capacity from the traction battery upon receiving user confirmation. The processor is further configured to adjust the battery life score and reserve battery capacity based on a calculated effect of the reserve battery capacity release.

The battery management controller may include the processor being further configured to monitor battery temperature during periods of elevated charge levels.

The battery management controller may include the processor calculating the battery life score using historical charging and discharging patterns.

The battery management controller may include the global navigation satellite system providing real-time updates to the processor for determining the predefined distance from a charging facility.

The battery management controller may include the processor being further configured to calculate the extended driving range achievable with the reserve battery capacity.

The battery management controller may include the processor being configured to prioritize reserve battery capacity release during pursuit conditions.

The battery management controller may include the processor being configured to prevent reserve battery capacity release when the battery life score indicates excessive degradation.

The battery management controller may include the processor being configured to store and analyze data related to previous reserve battery capacity releases to optimize future reserve management.

The battery management controller may include reserve battery capacity release being triggered automatically when the electric vehicle enters a predefined pursuit mode.

The battery management controller may include reserve battery capacity release options that include multiple stages based on the user’s driving destination and remaining range.

The battery management controller may include the system communicating with cloud-based services to update battery performance metrics and charging facility data.

In yet another aspect of the disclosure, a non-transitory computer-readable medium comprising instructions is presented. The instructions, when executed by one or more computing devices, cause the devices to perform operations for managing battery reserve capacity. The operations include monitoring battery usage patterns of an electric vehicle to calculate a battery life score and determining a reserve battery capacity based on the battery life score. The operations further include detecting when the electric vehicle is at a predefined distance from a charging facility and calculating an extended driving range based on the reserve battery capacity. The operations also include displaying a reserve battery capacity release option to a user, including the extended driving range and the battery life score effect of the reserve battery capacity release. The operations further include releasing the reserve battery capacity upon user confirmation and adjusting the battery life score and reserve battery capacity based on the effect of the reserve battery capacity release.

### BRIEF DESCRIPTION OF THE DRAWINGS

FIG. 1 illustrates a system architecture for managing reserve battery capacity in an electric vehicle;

FIG. 2 illustrates a pursuit mode decision-making flow for managing reserve battery capacity in an electric vehicle during important scenarios;

FIG. 3 illustrates a process for monitoring and adjusting reserve battery capacity and generating maintenance schedules to optimize battery health and performance;

FIG. 4 illustrates a process for evaluating battery life effects and calculating reserve capacity release in electric vehicles;

FIG. 5 illustrates a process for dynamically managing reserve battery capacity in response to battery life assessments and real-time driving conditions;

FIG. 6 illustrates a process for dynamically managing reserve battery capacity based on vehicle location and real-time battery assessment; and

FIG. 7 illustrates an example of a computing device for managing reserve battery capacity in electric vehicles.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

In priority driving scenarios or during high-demand operations, such as professional fieldwork or public responders, additional energy may be required to complete tasks or reach a location. While some solutions have temporarily unlocked reserve battery capacity to extend range, these approaches are limited in flexibility and user control. There remains a need for dynamic and efficient methods to address range anxiety and ensure vehicles may reliably meet the demands of diverse and challenging conditions.

The present disclosure relates to systems and methods for intelligent management of reserve battery capacity in electric vehicles. While the following detailed description focuses on specific implementations, those skilled in the art will recognize that variations and modifications are possible without departing from the spirit and scope of the disclosure.

The battery management system described herein comprises a sophisticated battery management controller that forms the core of an intelligent power management ecosystem within the vehicle. This controller integrates deeply with multiple vehicle subsystems through a high-speed vehicle data network, maintaining constant communication with the battery monitoring system, thermal management systems, vehicle dynamics controllers, navigation systems, and user interface components. The controller includes specialized processors optimized for real-time data processing and predictive analytics, working in conjunction with dedicated memory systems that maintain detailed historical operation logs while enabling rapid access to critical parameters during vehicle operation.

The functionality includes continuous monitoring and analysis of battery cycling patterns. The controller implements advanced data collection algorithms that track multiple parameters simultaneously across different timeframes. These parameters include instantaneous measurements such as cell voltages, current flow, and temperature distributions, as well as derived metrics such as depth of discharge trends and charge acceptance rates. The system monitors deep discharge events, maintaining detailed logs of not just the frequency and depth of such events, but also the surrounding conditions including ambient temperature, vehicle load demands, and terrain characteristics that may have contributed to the discharge pattern.

The monitoring system employs pattern recognition algorithms to characterize charging behavior, with particular emphasis on fast charging events. When a vehicle connects to a high-power charging station, the controller records comprehensive charging session data including initial state of charge, charging power profiles, thermal responses across the battery pack, and charging efficiency metrics. The system correlates this charging data with environmental conditions and battery state parameters to build a detailed understanding of how different charging patterns effect battery health under various conditions.

Temperature monitoring takes place through an array of strategically placed sensors throughout the battery pack, with additional sensors tracking ambient conditions. The controller maintains thermal history logs that correlate temperature distributions with charge states, usage patterns, and environmental conditions. This thermal data proves particularly important during periods of high state of charge, as elevated temperatures combined with high voltage states may increase various degradation mechanisms within the battery cells. The system uses this information to implement protective measures such as adjusting charging power limits or triggering additional cooling system capacity when needed to protect long-term battery health.

Temperature monitoring takes place through an array of strategically placed sensors throughout the battery pack, with additional sensors tracking ambient conditions. Data from these sensors is transmitted to the controller via a wired or wireless high-speed communication network, such as controller area network (CAN) or Ethernet, which may operate at sufficient speeds for effective data transmission. The controller maintains thermal history logs that correlate temperature distributions with charge states, usage patterns, and environmental conditions. This thermal data proves particularly relevant during periods of high state of charge, as elevated temperatures combined with high voltage states may increase the rate of various degradation mechanisms within the battery cells. The system uses this information to implement protective measures, such as adjusting charging power limits or triggering additional cooling system capacity when needed, to protect long-term battery health.

The controller employs advanced machine learning algorithms to calculate the battery life (typically ten-year life) score, processing the collected usage data through multiple analysis layers. The scoring system considers not just the obvious factors such as charge/discharge cycles, but also more subtle influences such as time spent at various state-of-charge levels, thermal exposure histories, and power demand profiles. The algorithm applies scientifically derived weighting factors to each parameter based on established battery aging models and real-world degradation data. These weighting factors are continuously refined through over-the-air updates as new battery aging data becomes available from the vehicle fleet. The controller may maintain an updated database of charging station locations, types, and historical availability patterns. This data is integrated with topographical information and real-time weather data, potentially transmitted via networks such as cellular or Wi-Fi operating at sufficient speeds for effective data transmission. The system calculates dynamic range thresholds that determine when a vehicle is considered to be in a remote location, accounting for elevation changes, temperature effects on battery performance, and historical energy consumption patterns for similar routes and conditions.

The controller may sample data at a predefined frequency (e.g., 100 Hz), tracking individual cell voltages with 1mV resolution, current flow may be measured by Hall effect sensors with 0.1A precision, and temperature distributions may be mapped through a matrix of thermistors providing 0.1°C accuracy. This sampling may be achieved through a high-speed communication protocol, such as CAN or similar networks which may operate at speeds sufficient for effective data transmission, ensuring robust data acquisition. Derived metrics, including averages of depth of discharge, charge acceptance rates, and internal resistance trends, are continuously updated. The system monitors deep discharge events, maintaining detailed logs of not just the frequency and depth of such events but also the surrounding conditions, such as ambient temperature, vehicle load demands, and terrain characteristics that may have contributed to the discharge pattern.

The monitoring system employs pattern recognition algorithms to characterize charging behavior, with particular emphasis on fast charging events. Responsive to a vehicle connecting to a high-power charging station, the controller records comprehensive charging session data, including initial state of charge, charging power profiles, thermal responses across the battery pack, and charging efficiency metrics. These data points may be collected through a network such as controller area network flexible data rate (CAN-FD), which may operate at sufficient speeds for high-resolution tracking. The system correlates this charging data with environmental conditions and battery state parameters to build a detailed understanding of how different charging patterns effect battery health under various conditions.

The system’s location awareness capabilities extend beyond a simple global navigation satellite system (GNSS) to include detailed mapping of charging infrastructure availability. The controller maintains an updated database of charging station locations, types, and historical availability patterns. This data integrates with topographical information and real-time weather data to calculate dynamic range thresholds that determine when a vehicle is considered to be in a remote location. The threshold calculations account for factors such as elevation changes, temperature effects on battery performance, and historical energy consumption patterns for similar routes and conditions.

When operating in remote locations, the system implements sophisticated algorithms to determine acceptable reserve capacity release amounts. These calculations consider multiple factors simultaneously, including the current battery health score, precise distance to various charging options, real-time power consumption trends, and projected energy needs based on route characteristics and activated vehicle systems. The controller uses predictive modeling to estimate how different reserve capacity release amounts might affect both immediate operational needs and long-term battery longevity.

The user interface provides comprehensive information through a display system that communicates complex battery management decisions in an easily understandable format. For standard consumer vehicles, the interface presents clear visualizations of current range projections, available reserve capacity, and the implications of different reserve release options. The display integrates with the navigation system to show dynamic range circles that update in real-time based on terrain, weather, and driving style. When reserve capacity release is available, the interface presents users with detailed information about potential range extensions and any associated long-term effects, using clear graphics and simple language to ensure informed decision-making.

For priority vehicles, the system implements a more sophisticated control scheme that may automatically engage reserve capacity release based on vehicle operational states. Responsive to priority indication systems such as lights and sirens activating, the controller immediately begins a staged release of reserve capacity, carefully monitoring power demands and adjusting the release rate to maintain optimal performance while preserving as much long-term battery health as possible. Additionally, the system supports pursuit mode, which may include scenarios involving rescue, police, or medical service operations. Pursuit mode may encompass activities such as extended travel at high speeds, rapid rate of speed increase to reach locations, or maintaining power-intensive auxiliary systems such as sirens, radios, or lighting equipment. In pursuit mode, the controller prioritizes continuous energy availability by dynamically adjusting reserve capacity release rates, considering factors such as distance to known charging infrastructure, predicted power usage, and battery temperature thresholds. The system may also integrate real-time updates from the navigation system to provide route optimization, ensuring the vehicle can complete its task while conserving sufficient energy for return travel or immediate charging access. The system continuously calculates return distances and maintains awareness of charging infrastructure availability, ensuring that pursuit operations may be completed while maintaining adequate energy reserves for return.

The trail operation features incorporate advanced terrain analysis capabilities that work in conjunction with specialized trail mapping applications. When a vehicle enters an off-pavement area, the system accesses detailed trail data including surface type, difficulty ratings, elevation profiles, and historical energy consumption patterns from other vehicles that have traversed the same trail. This information feeds into sophisticated energy consumption models that predict power requirements for different sections of the trail, allowing the system to make intelligent decisions about reserve capacity allocation.

The navigation integration extends beyond simple route planning to include comprehensive energy management strategies. The system considers multiple routing options simultaneously, evaluating each potential path based on factors such as elevation changes, traffic conditions, weather effects, and the availability of charging infrastructure. For each route option, the controller calculates detailed energy consumption projections and determines the optimal use of available battery capacity, including reserve energy if needed. The navigation system maintains constant awareness of backup options such as towing service access points and areas with reliable cellular coverage, ensuring that help may be reached if energy consumption exceeds projections.

The return to protected status process involves more than simply restricting access to reserve capacity. When conditions allow for reversion to protected status, the system implements a process that includes detailed analysis of how the reserve capacity was used. This analysis includes evaluation of discharge rates, temperature profiles during usage, and any observed changes in battery performance metrics. The system uses this information to update its battery health models and adjust future reserve capacity release thresholds accordingly.

The maintenance management aspects of the system employ sophisticated predictive analytics to optimize battery longevity. The controller maintains separate usage logs for different operational modes, allowing the controller to develop detailed understanding of how various use patterns effect battery health. This information feeds into adaptive maintenance scheduling algorithms that may recommend specific actions to optimize battery life based on observed usage patterns and projected future needs.

The system architecture allows for implementation across various electrified vehicle platforms through configurable software parameters and modular hardware interfaces. The core battery management strategies may be adapted to different battery chemistries and vehicle architectures while maintaining the fundamental protective features and intelligent reserve capacity management capabilities. This flexibility enables broad application of the technology across different vehicle types and use cases while maintaining optimal performance for each specific implementation.

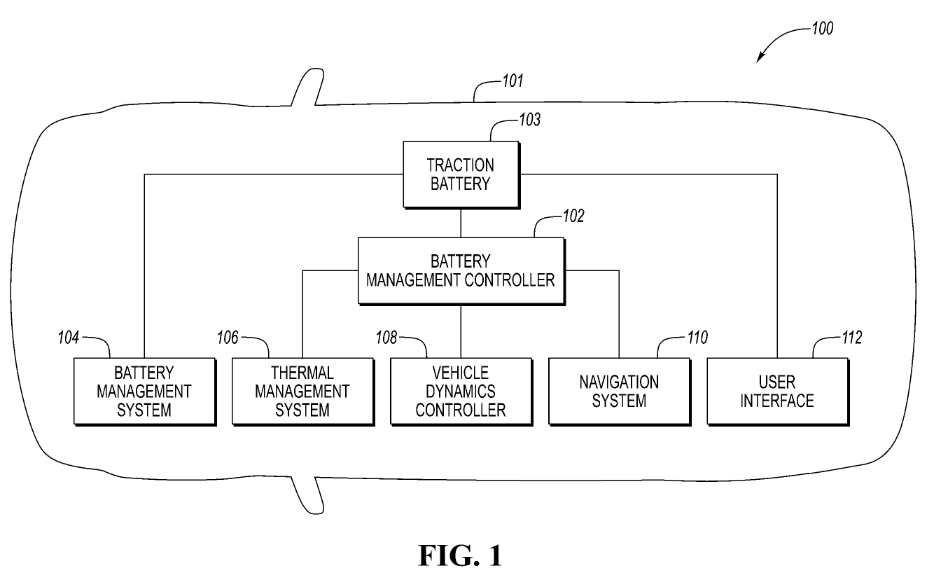

FIG. 1 illustrates a system architecture 100 for managing reserve battery capacity in a vehicle 101, including a battery management controller 102 for a traction battery 103, a battery management subsystem 104, a thermal management subsystem 106, a vehicle dynamics controller 108, a navigation subsystem 110, and a user interface 112. Together, these subsystems, connected via a high-speed communication network such as CAN-FD, enable the battery management controller 102 to make intelligent decisions about reserve capacity management, protecting long-term battery health while addressing real-time operational needs. It should be noted that the system architecture 100 is only an example, and more, fewer, and/or differently arranged elements may be used to perform the disclosed operations.

The vehicle 101 may be any various types of automobile, crossover utility vehicle (CUV), sport utility vehicle (SUV), truck, recreational vehicle, boat, plane or other mobile machine for transporting people or goods. Such vehicles 101 may be human-driven or autonomous. In many cases, the vehicle 101 may be a battery electric vehicle powered by one or more electric motors receiving power from a traction battery 103. As a further possibility, the vehicle 101 may be a hybrid electric vehicle powered by both an engine and one or more electric motors. As the type and configuration of vehicle 101 may vary, the capabilities of the vehicle 101 may correspondingly vary. As some other possibilities, vehicles 101 may have different capabilities with respect to passenger capacity, towing ability and capacity, and storage volume. For title, inventory, and other purposes, vehicles 101 may be associated with unique identifiers, such as vehicle identification numbers (VINs).

The traction battery 103 refers to a type of rechargeable battery specifically designed to provide power to the electric motors of electric or hybrid vehicles 101. The traction battery 103 may be constructed using various battery chemistries, such as lithium ion, that are designed for high power-to-weight ratio and good energy density. To ensure the life of the traction battery 103, the traction battery 103 may integrate thermal management features as well as sensors to measure the operational state of the traction battery 103.

The battery management controller 102 may be configured to integrate and coordinate the various subsystems and controllers of the system architecture 100 to ensure optimal performance and battery health of the traction battery 103. Thus, the battery management controller 102 may be configured to manage the performance of the various flows and processes discussed in detail herein.

The battery management subsystem 104 may monitor key battery parameters of the traction battery 103 based on the sensors of the traction battery 103. These parameters may include, as some examples, cell voltages (e.g., with resolutions up to 1 mV), current flow (e.g., using precision sensors which may be monitored with 0.1 A sensitivity), and temperature distributions (which may be monitored through thermistors with 0.1°C accuracy). The battery management subsystem 104 may be used to provide data on depth of discharge, charge/discharge patterns, and thermal conditions to the battery management controller 102 for real-time analysis.

The thermal management subsystem 106 may be configured to ensure the thermal stability of the traction battery 103 using the thermal management features of the traction battery 103. In an example, the thermal management subsystem 106 may perform operations such as dynamically adjusting cooling mechanisms and analyzing temperature distributions to prevent overheating. In some examples, these cooling adjustments may be invoked responsive to operations that involve significant battery charge or discharge, such as reserve capacity release or fast charging events.

The vehicle dynamics controller 108 may be configured to contribute to intelligent energy management by analyzing power demands based on operation of the vehicle 101. For example, the vehicle dynamics controller 108 may monitor the vehicle bus or other data sources to capture information with respect to driving conditions, such as terrain, load, and demand on the traction battery 103, to provide functions such as terrain analysis and estimated energy consumption.

The navigation subsystem 110 integrates a charging infrastructure database with route optimization tools, using real-time weather, elevation, and topographical data to calculate efficient routes and ensure reachability to charging facilities or exit points during off-pavement which may be cement, asphalt, or paver bricks operations. In an example, the navigation subsystem 110 may make use of GNSS functionality of the vehicle 101 to determine the current location of the vehicle 101 and/or distance of the vehicle 101 to charging stations or other points of interest. The navigation subsystem 110 may be further configured to estimate the energy usage required from the traction battery 103 in order to cause the vehicle 101 to traverse the route.

The user interface 112 is configured to provide a human-machine interface (HMI) that allows vehicle occupants to understand current range, reserve capacity projections, and the potential effect of reserve usage on battery health, enabling informed decision-making. To do so, user interface 112 may utilize display screens to provide information visually, speakers to provide information audibly, buttons or touch panel displays to receive touch input, and/or microphones to receive voice input.

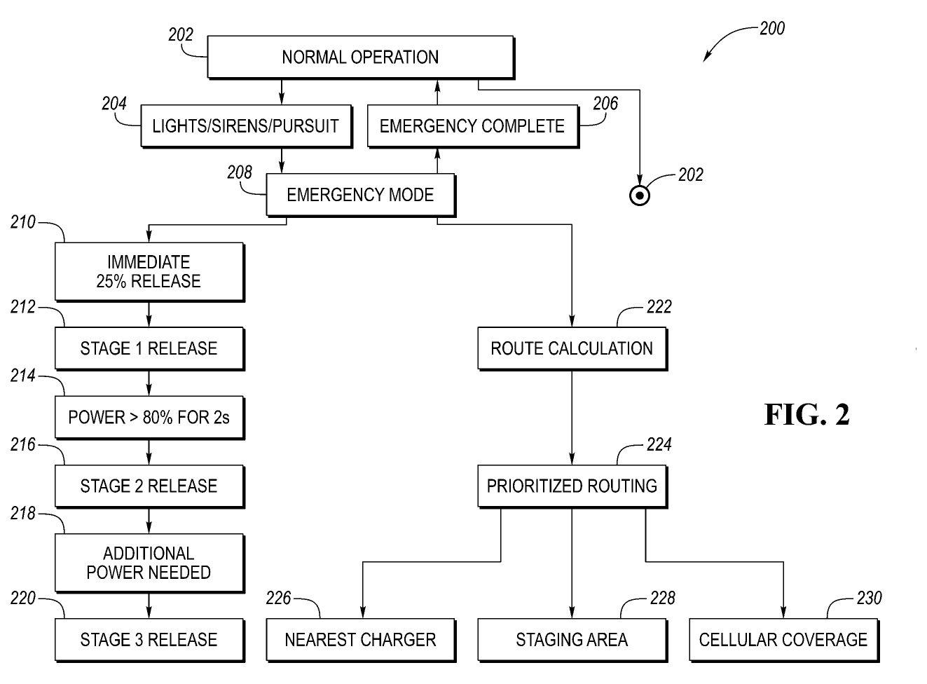

FIG. 2 illustrates a pursuit mode decision-making flow 200 for managing reserve battery capacity in the vehicle 101 during important scenarios. In an example, the pursuit mode decision-making flow 200 may be performed by the components of the system architecture 100 discussed in detail herein.

The pursuit mode decision-making flow 200 begins in normal operation 202, where the vehicle 101 operates without reserve capacity release. Upon the activation of priority indication systems, such as lights or sirens 204 the system architecture 100 transitions the vehicle 101 into a pursuit mode 208. This may include initiating a staged release of reserve battery capacity. The vehicle 101 may exit the pursuit mode 208 and return to normal operation 202 responsive to a pursuit being marked as complete 206. The vehicle 101 may continue to remain in normal operation 202 if there is no activation of the pursuit mode 208.

The pursuit mode 208 may include one or more stages of reserve capacity release 210. In a first of these stages, an immediate 25% reserve capacity release 210 is triggered to ensure adequate power availability for pursuit operations. If additional power is required, the system architecture 100 transitions the vehicle 101 moves to Stage 1 Release 212, where battery power output is evaluated. If the system architecture 100 detects power exceeding an upper threshold, for example 80%, for a sustained duration of time, for example two seconds 214, the system architecture 100 transitions the vehicle 101 to a Stage 2 Release 216, providing a further release of reserve energy. Should the energy demands continue to rise, an additional check determines whether further reserve capacity is necessary 218, leading to a Stage 3 Release 220, which allocates maximum available reserve capacity.

Parallel to the reserve release process, the system architecture 100 calculates pursuit routes through a route calculation 222. This includes prioritizing paths based on factors via prioritized routing 224, such as locating a nearest charging station 226, directing to a staging area 228, or ensuring routes maintain cellular coverage 230 for uninterrupted communication with pursuit services. These routing decisions are dynamically updated in real time to reflect changes in conditions or performance of the vehicle 101.

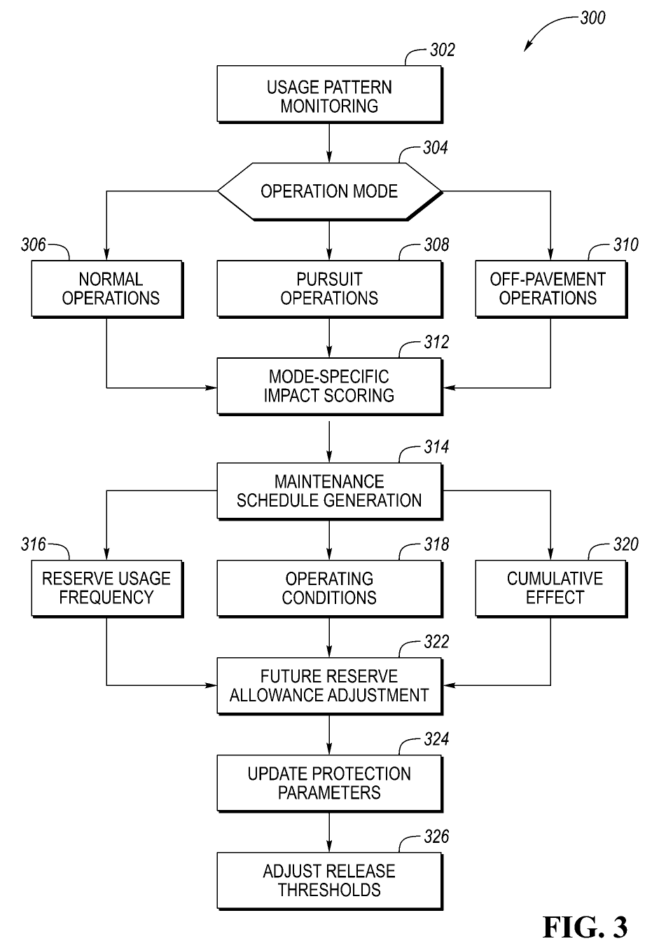

FIG. 3 illustrates a process 300 for monitoring and adjusting reserve battery capacity and generating maintenance schedules to optimize battery health and performance. As with the pursuit mode decision-making flow 200, the process 300 may also be performed by the components of the system architecture 100 controlling the vehicle 101.

The process 300 begins with usage pattern monitoring 302, where the system collects real-time and historical data on battery usage patterns, including charge/discharge cycles, temperature variations, and reserve capacity utilization. This information is used to determine an operation mode 304, which are categorized into three distinct modes: Normal Operations 306, Pursuit Operations 308, or Off-Pavement Operations 310.

The off-pavement operations 310 includes operations where the vehicle 101 operates outside of pavement surfaces such as cement, asphalt, or paver bricks. The off-pavement surfaces may include terrain such as on gravel, dirt or soil, sand, grass, mulch or wood chips, or unpaved compacted paths.

For each operation mode 304, the system performs a mode-specific effect scoring 312 to evaluate how the battery is affected under the corresponding conditions. This scoring incorporates factors such as energy consumption trends, depth of discharge, and thermal effects. The results of the effect scoring feed into a maintenance schedule generation 314, which organizes required actions based on three primary factors: reserve usage frequency 316, operating conditions 318, and cumulative effect 320. This ensures that the battery is maintained proactively, based on its usage and performance data.

Following the maintenance schedule generation 314, the system calculates adjustments to future reserve allowance 322 by analyzing the frequency of reserve usage, the severity of the operating conditions 318, and the cumulative effect 320 of reserve discharges on battery longevity. Using this analysis, the system proceeds to update protection parameters 324, modifying thresholds and limits to maintain long-term battery health of the traction battery 103. These updates may include recalibrating metrics such as minimum reserve levels and discharge depths, ensuring that the system dynamically adapts to the battery’s evolving state.

The process 300 may also performs an operation to adjust release thresholds 326, where it fine-tunes the criteria for reserve capacity release 210. These adjustments ensure that reserve energy is allocated intelligently across different operational modes, balancing immediate needs with the preservation of long-term battery performance. Accordingly, the process 300 demonstrates a holistic approach for the system architecture 100 to direct the vehicle 101 to integrate real-time monitoring, effect analysis, and adaptive maintenance to enhance longevity and operational reliability of the traction battery 103.

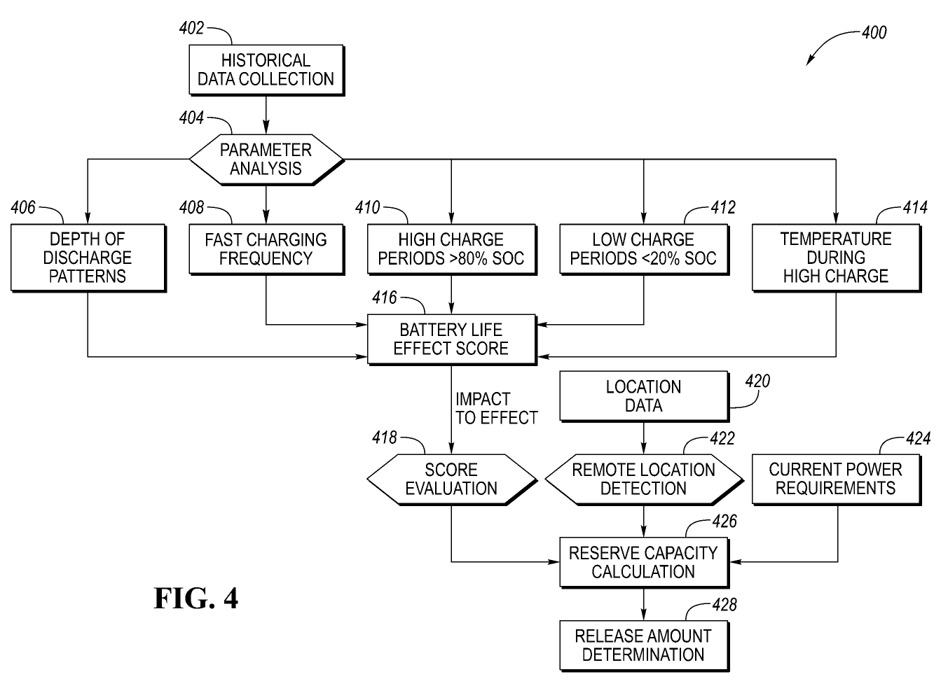

FIG. 4 illustrates a process 400 for evaluating battery life effects and calculating reserve capacity release 210 in vehicles 101. As with the pursuit mode decision-making flow 200 and the process 300, the process 400 may also be performed by the components of the system architecture 100 controlling the vehicle 101.

The process 400 begins with historical data collection 402, where the system architecture 100 continuously gathers detailed usage data, including charging patterns, discharge events, and environmental factors.

This data feeds into parameter analysis 404, where specific factors affecting battery health are assessed. These parameters may include, as some non-limiting examples, depth of discharge patterns 406, frequency of fast charging 408, high charge periods above a defined threshold (for example 80%) for state of charge (SOC) 410, low charge periods below a defined threshold (for example) 20% SOC 412, and temperature during high charge states 414.

The insights from this analysis are used to calculate a battery life effect score 416, which quantifies the cumulative effect 320 of these factors on battery degradation. This score is then subjected to score evaluation 418 to determine its implications for reserve capacity management. In parallel, the system architecture 100 integrates location data 420 (e.g., using the GMSS functions of the navigation subsystem 110) to identify whether the vehicle 101 is operating in a remote location 422, a useful factor for calculating energy needs when access to charging stations is limited.

Additionally, the system architecture 100 considers current power requirements 424 based on real-time vehicle 101 demands. This information may be captured, for example, using the vehicle dynamics controller 108.

Using this combined data, the system architecture 100 proceeds to perform a reserve capacity calculation 426, where the process 400 determines the optimal amount of reserve energy that may be released without compromising long-term battery health.

Next, the system architecture 100 performs a release amount determination 428. This includes the system architecture 100 specifying an exact reserve capacity to be made available for immediate use based on the operational needs, the environmental conditions, and the calculated battery effect score.

Thus, the process 400 provides an integrated approach to reserve battery capacity management, combining real-time monitoring, predictive analytics, and adaptive control strategies to optimize battery utilization while maintaining long-term reliability. The operations of the process 400 as performed by the system architecture 100 operate to adapts to varying operational demands while preserving battery health of the traction battery 103 through protection mechanisms and intelligent release protocols.

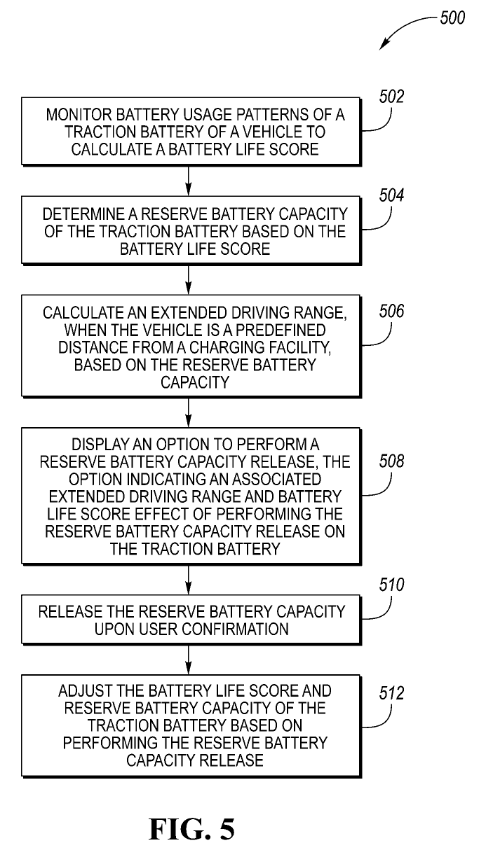

FIG. 5 illustrates a process 500 for dynamically managing reserve battery capacity in response to battery life assessments and real-time driving conditions. The process 500 may be performed by the components of the system architecture 100 controlling the vehicle 101.

The process 500 begins with monitoring battery usage patterns 502, where the system architecture 100 continuously collects real-time and historical battery usage data to calculate a battery life score. The battery life score serves as an indicator of overall battery health and longevity, incorporating factors such as depth of discharge cycles, thermal stress events, and charge/discharge efficiency. The system monitors instantaneous parameters such as individual cell voltages, temperature distributions, and current flow trends while also tracking long-term operational characteristics. The battery management controller 102 processes this data using predictive analytics and machine learning algorithms to identify usage trends and degradation patterns.

Based on the battery life score, the system determines a reserve battery capacity 504 of the traction battery 103. The reserve battery capacity represents a portion of stored energy that remains inaccessible under normal driving conditions but may be selectively released under specific circumstances. The system dynamically adjusts the reserve battery capacity based on real-time assessments of battery health, prioritizing long-term durability while ensuring pursuit energy availability when needed. The battery management subsystem 104 continuously refines these determinations by evaluating charge retention performance, internal resistance trends, and historical energy demands.

Using the available reserve battery capacity, the system calculates an extended driving range 506 when the vehicle 101 is detected to be a predefined distance from a charging facility. This calculation integrates multiple factors, including vehicle efficiency metrics, road conditions, elevation profiles, and expected energy consumption rates along the route. The navigation subsystem 110 plays a key role in these calculations by cross-referencing known charging station locations, estimated power requirements, and anticipated weather conditions that may affect battery efficiency. The extended driving range estimation ensures that the vehicle 101 can reach a charging facility before exhausting its main energy reserves.

Once the extended range determination is complete, the system displays an option 508 for the driver to release reserve battery capacity. This user interface 112 notification provides clear information about the effect of the reserve battery capacity release, including the additional driving range that may be gained and the potential effect on the battery life score. The system may present a visual representation of the extended range using navigation overlays, indicating available charging stations and estimated arrival energy levels. Additionally, the interface may provide notifications if the battery life score suggests that reserve usage could facilitate long-term degradation beyond acceptable thresholds.

Upon user confirmation, the system executes the release of the reserve battery capacity 510. This process involves modifying internal discharge limits within the traction battery 103 to grant temporary access to the stored energy. The release operation is carefully controlled by the battery management controller 102 to ensure power is delivered in a manner that minimizes thermal stress and maintains overall battery stability. During this process, the vehicle dynamics controller 108 continuously monitors real-time energy consumption rates and adjusts power delivery parameters accordingly to optimize efficiency and range extension.

Following the reserve battery capacity release, the system performs adjustments to the battery life score and reserve battery capacity 512. These adjustments are based on the observed effect of the reserve usage event, with factors such as discharge rate, temperature fluctuations, and total energy expended being analyzed to refine future battery management decisions. The system architecture 100 updates its predictive models accordingly, ensuring that subsequent reserve battery capacity determinations reflect the latest battery performance data. The revised battery life score is then displayed to the driver, allowing for informed decision-making regarding future energy management.

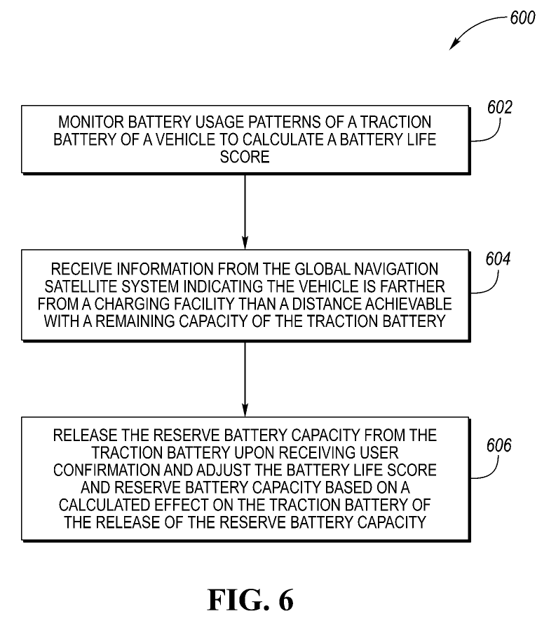

FIG. 6 illustrates a process 600 for dynamically managing reserve battery capacity based on vehicle location and real-time battery assessments. The process 600 is executed by a processor, such as the battery management controller 102, which integrates battery usage monitoring, navigation data, and user input to optimize battery performance and vehicle range.

The process 600 begins with monitoring battery usage patterns 602 to calculate a battery life score. The processor continuously collects data on charge and discharge cycles, thermal conditions, depth of discharge trends, and charging behaviors. This information is processed using machine learning algorithms and predictive models to generate a comprehensive battery life score that reflects the overall health of the traction battery 103. The scoring system considers real-time operational data, including energy consumption rates, temperature variations, and past reserve capacity usage. The battery management subsystem 104 provides the processor with continuous updates on battery health and degradation indicators.

The processor then receives information from the global navigation satellite system (GNSS) 604 to determine the vehicle’s location relative to known charging infrastructure. The navigation subsystem 110 provides real-time positioning data, which is cross-referenced with a database of charging stations, topographical information, and estimated travel energy consumption. The processor analyzes this data to determine whether the vehicle 101 is located beyond a threshold distance where the remaining charge in the traction battery 103 would be insufficient to reach a charging facility. This determination incorporates variables such as elevation changes, traffic conditions, weather effects, and historical energy consumption patterns. If the system identifies that the vehicle 101 may deplete its available energy before reaching a charging station, the processor prepares for a reserve battery capacity release.

Once a determination is made that reserve battery capacity may be needed, the processor initiates a user prompt and, upon confirmation, releases the reserve battery capacity 606. The user interface 112 presents the driver with an option to extend the vehicle's range by accessing reserve energy, providing clear data on the estimated additional driving distance and the potential effect on the battery life score. Upon user confirmation, the processor commands the battery management controller 102 to modify internal discharge limits, allowing access to the previously restricted energy reserves.

Following the reserve battery capacity release, the processor adjusts the battery life score and reserve battery capacity allocation based on the observed effects of the release. This adjustment accounts for factors such as discharge rate, thermal effect, and the depth of reserve utilization. The updated battery life score is stored within the system and used for future calculations regarding battery health and reserve management. The processor may also update thresholds for subsequent reserve releases, ensuring that reserve energy remains available when necessary while optimizing long-term battery performance.

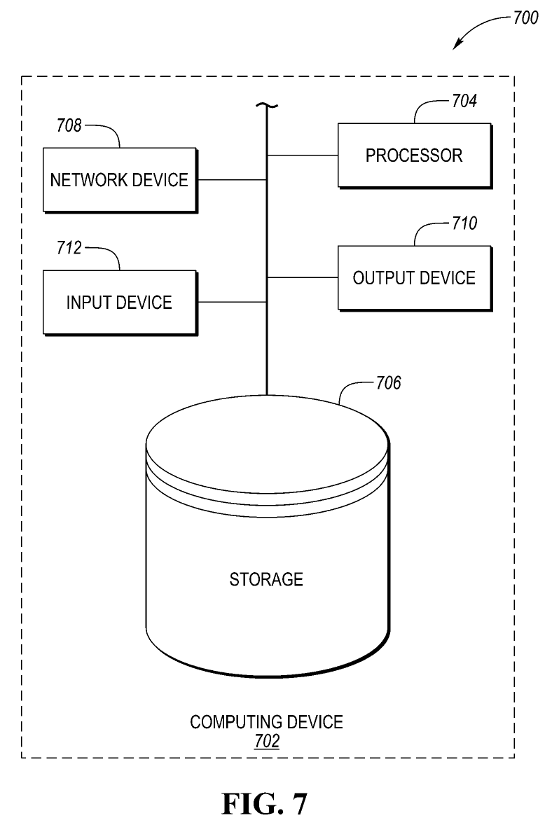

FIG. 7 is an example 700 of a computing device 702 for managing reserve battery capacity in vehicles 101. As shown, the computing device 702 includes a processor 704 operatively connected to a storage 706, a network device 708, an output device 710, and an input device 712. It should be noted that this is merely an example, and computing devices 702 with more, fewer, or different components may be used.

The processor 704 may include one or more integrated circuits that implement the functionality of a central processing unit (CPU) and/or a graphics processing unit (GPU). In some examples, the processor 704 is a system on a chip that integrates the functionality of the CPU and GPU. The SoC may also optionally include other components, such as the storage 706 and the network device 708, into a single integrated device. Alternatively, the CPU and GPU may be connected to each other via a peripheral connection device such as peripheral component interconnect (PCI) express or another suitable data connection. The CPU may be a commercially available device implementing an instruction set such as x86, ARM, Power, or microprocessor without interlocked pipeline stage (MIPS) instruction set families.

During operation, the processor 704 executes program instructions stored in the storage 706. These instructions enable the processor 704 to perform tasks such as monitoring battery usage patterns, calculating a battery life score, determining reserve battery capacity, and coordinating the release of reserve capacity based on vehicle distance from charging facilities, terrain, and other factors. The processor 704 may also integrate data from subsystems such as navigation, thermal management, and vehicle dynamics to enhance battery management strategies.

The storage 706 includes non-volatile and volatile memory. Non-volatile memory may include solid-state storage such as NAND flash memory, magnetic storage, or optical media, which retains data even when power is removed. Volatile memory may include random access memory (RAM) that stores data and program instructions while the computing device 702 is in operation. The storage 706 may contain historical battery usage data, environmental factors, and charging infrastructure information.

The network device 708 allows communication with external systems, such as cloud-based services that update battery health metrics and charging facility locations. The network device 708 may also transmit system-generated data, such as reserve battery usage history or performance metrics, to remote servers for fleet-wide analysis and optimization. Examples of suitable network devices include Ethernet interfaces, Wi-Fi transceivers, cellular transceivers, BLUETOOTH adapters, or ultra-wideband (UWB) transceivers.

The output device 710 provides visual, auditory, or tactile feedback to the driver, displaying critical information such as reserve capacity release 210 options, battery health metrics, and estimated range extensions. Examples of output devices include electronic display screens, speakers, and devices for tactile feedback such as braille displays. For example, the output device 710 may graphically show the vehicle’s current range, the additional range achievable with reserve capacity, and the effect of reserve release on long-term battery health.

The input device 712 enables user interaction with the computing device 702. It allows the user to configure the system, confirm reserve capacity release 210, and adjust system parameters such as range thresholds. Suitable input devices include touchscreens, keyboards, voice input systems, and other human-machine interface devices.

The processor 704, working with the storage 706 and network device 708, also supports real-time location-based calculations. For example, when the vehicle is farther from a charging facility than the range achievable with its current battery capacity, the processor 704 calculates whether reserve capacity can bridge the gap. If so, the system notifies the driver via the output device 710 and requests confirmation through the input device 712 to release reserve capacity.

The computing device 702 integrates seamlessly with the vehicle’s battery management subsystem 104, thermal management subsystem 106, and navigation subsystem 110 to provide intelligent reserve capacity management. This integration ensures that the reserve release process dynamically adapts to real-time conditions, including terrain, weather, and vehicle usage patterns, while protecting long-term battery health.

The system architecture 100 supports implementation across various vehicle platforms. It combines hardware components, such as application-specific integrated circuits (ASICs) or field-programmable gate arrays (FPGAs), with software and firmware to deliver robust and scalable solutions. This enables a flexible, reliable approach to managing battery reserve capacity under diverse operational scenarios, including high-demand, pursuit, and off-road conditions.

The processes, methods, and algorithms disclosed in the present application for managing reserve battery capacity in vehicles 101 can be implemented using a processing device, controller, or computing system. These implementations may involve a programmable electronic control unit (ECU), a dedicated battery management controller 102, or other suitable control devices within the vehicle’s power management system. The disclosed processes and methods may be stored as data and executable instructions on various storage media, such as read-only memory (ROM), random-access memory (RAM), solid-state storage devices (e.g., NAND flash memory), or magnetic storage devices. Alternatively, the processes, methods, and algorithms may be embedded in software applications or partially or wholly implemented in hardware, such as ASICs, FPGAs, or state machines. In some cases, these implementations may be a combination of hardware, software, and firmware components integrated into the vehicle’s architecture.

In this application, the first instance of an acronym or abbreviation defines its meaning for all subsequent uses, including grammatical variations, unless explicitly stated otherwise. Measurements of properties, such as battery capacity, thermal conditions, or range, are determined using the same techniques referenced elsewhere in the specification unless explicitly described otherwise.

As used herein, the singular terms “a,” “an,” and “the” are inclusive of plural forms unless the context clearly indicates otherwise. For example, a reference to “a battery” includes one or more batteries unless explicitly stated otherwise.

The term “comprising” as used in this application means “including,” “having,” “containing,” or “characterized by,” and is open-ended, allowing for the inclusion of additional, unrecited elements or steps. In contrast, “consisting of” excludes any element or step not explicitly specified. When “consisting of” appears in a claim clause, it limits only that clause and not the claim as a whole. The phrase “consisting essentially of” permits the inclusion of additional elements or steps as long as they do not materially affect the basic or novel characteristics of the claimed invention. The terms “one or more” and “at least one” mean “one or more” and include the concept of “plurality.”

The specific embodiments described herein are intended to provide examples of the disclosed system and methods for managing reserve battery capacity, but they do not limit the full scope of the invention. Modifications and adaptations may be made without departing from the spirit of the disclosure. For instance, different combinations of hardware and software may be used to implement the system, and features from various embodiments can be combined to create additional embodiments that may not be explicitly described.

Certain embodiments of the present disclosure are described as advantageous or preferable for specific applications, such as improving range in remote conditions, preserving long-term battery health, or dynamically adapting reserve management during priority operations. However, these attributes may vary depending on the desired trade-offs for a specific implementation, such as design requirements, durability, manufacturability, or user experience. Even embodiments described as less preferable for certain characteristics are still within the scope of this disclosure and may be desirable for particular use cases.

What is claimed is:

1. A method for managing battery reserve capacity comprising:
monitoring battery usage patterns of a traction battery of a vehicle to calculate a battery life score;
determining a reserve battery capacity of the traction battery based on the battery life score;
calculating an extended driving range, when the vehicle is a predefined distance from a charging facility, based on the reserve battery capacity;
displaying an option to perform a reserve battery capacity release, the option indicating an associated extended driving range and battery life score effect of performing the reserve battery capacity release on the traction battery;
releasing the reserve battery capacity upon user confirmation; and
adjusting the battery life score and reserve battery capacity of the traction battery based on performing the reserve battery capacity release.

2. The method of claim 1 wherein monitoring the battery usage patterns includes tracking depth of discharge events and charge levels of the traction battery.

3. The method of claim 1 wherein calculating the battery life score includes accounting for thermal exposure and charging frequency.

4. The method of claim 1 wherein determining the reserve battery capacity includes ensuring the release does not exceed a predefined limit to maintain long-term battery health.

5. The method of claim 1 wherein the predefined distance is dynamically adjusted based on topographical data and weather conditions.

6. The method of claim 1 wherein displaying the option to perform the reserve battery capacity release includes presenting a graphical interface showing projected range and battery life effect.

7. The method of claim 1 wherein releasing the reserve battery capacity includes applying a staged release process based on operational requirements of the vehicle.

8. The method of claim 1 wherein adjusting the battery life score includes updating thresholds for future reserve capacity releases.

9. A battery management controller for managing battery reserve capacity comprising:
a traction battery configured to store and supply electrical energy to a vehicle;
a global navigation satellite system configured to determine a location of the vehicle; and
a processor configured to:
monitor usage patterns of the traction battery to calculate a battery life score and determine a reserve battery capacity based on the battery life score;
receive information from the global navigation satellite system indicating the vehicle is farther from a charging facility than a distance achievable with a remaining capacity of the traction battery; and
release the reserve battery capacity from the traction battery upon receiving user confirmation and adjust the battery life score and reserve battery capacity based on a calculated effect on the traction battery of the release of the reserve battery capacity.

10. The battery management controller of claim 9 wherein the processor is further configured to monitor battery temperature during periods of elevated charge levels.

11. The battery management controller of claim 9 wherein the processor calculates the battery life score using historical charging and discharging patterns.

12. The battery management controller of claim 9 wherein the global navigation satellite system provides real-time updates to the processor for determining a predefined distance from the charging facility.

13. The battery management controller of claim 9 wherein the processor is further configured to calculate an extended driving range achievable with the reserve battery capacity.

14. The battery management controller of claim 9 wherein the processor is configured to prioritize reserve battery capacity release during pursuit conditions.

15. The battery management controller of claim 9 wherein the processor is configured to prevent reserve battery capacity release when the battery life score indicates excessive degradation.

16. The battery management controller of claim 9 wherein the processor is configured to store and analyze data related to previous reserve battery capacity releases to optimize future reserve management.

17. The battery management controller of claim 9 wherein reserve battery capacity release is triggered automatically when the vehicle enters a predefined pursuit mode.

18. The battery management controller of claim 9 wherein reserve battery capacity release options include multiple stages based on a driving destination of the vehicle and remaining range.

19. The battery management controller of claim 9 wherein the system communicates with cloud-based services to update battery performance metrics and charging facility data.

20. A non-transitory computer-readable medium comprising instructions that, when executed by one or more computing devices, cause the devices to perform operations for managing battery reserve capacity, the operations comprising:
monitoring battery usage patterns of a traction battery of a vehicle to calculate a battery life score;
determining a reserve battery capacity based on the battery life score;
responsive to detecting when the vehicle is at a predefined distance from a charging facility:
calculating an extended driving range based on the reserve battery capacity;
displaying an option to perform a reserve battery capacity release , the option indicating the extended driving range and an effect of the reserve battery capacity release on the battery life score;
releasing the reserve battery capacity upon user confirmation; and
adjusting the battery life score and reserve battery capacity based on the effect of the reserve battery capacity release.
